(19) United States
(12) Patent Application Publication
(10) Pub. No.: US 2015/0079739 A1
(43) Pub. Date: Mar. 19, 2015

(54) METHOD FOR MANUFACTURING SEMICONDUCTOR SUBSTRATE

(71) Applicant: United Microelectronics Corp., Hsin-Chu City (TW)

(72) Inventor: CHEN CHEN, Singapore (SG)

(73) Assignee: United Microelectronics Corp., Hsin-Chu City (TW)

(21) Appl. No.: 14/027,249

(22) Filed: Sep. 16, 2013

(51) Int. Cl. H01L 29/66

(52) U.S. Cl. CPC H01L 29/665
USPC 438/197

(57) ABSTRACT

A method for manufacturing a semiconductor substrate includes following steps. A wafer having a front side and a back side is provided. A plurality of gate structures at least a first insulating layer covering the gate structures are formed on the front side of the wafer. At least a polysilicon layer and a second insulating layer are formed on the back side of the wafer. Subsequently, at least a source/drain is formed in the front side of the wafer. Next, the second insulating layer is removed from the back side of the wafer. After removing the second insulating layer, the polysilicon layer is removed from the back side of the wafer.

### BACKGROUND OF THE INVENTION

1. Field of the Invention

The invention relates to a method for manufacturing a semiconductor substrate, and more particularly, to a cleaning method for manufacturing a semiconductor substrate.

2. Description of the Prior Art

In semiconductor device manufacturing, semiconductor, dielectric, and conductor layers are formed on a substrate and etched to form patterns of gates, vias, contact holes and interconnect features. During those fabricating processes, impurities, residues, or contaminations are generated. Impurities, residues, or contaminations on the substrate are adverse, even vital, to not only the front side of the substrate, but also the back side of the substrate. Therefore, cleanliness of both sides of the substrate always is required.

### SUMMARY OF THE INVENTION

According to an aspect of the present invention, a method for manufacturing a semiconductor substrate is provided. According to the method for manufacturing the semiconductor substrate, a wafer having a front side and a back side is provided. At least a gate structure and a first insulating layer covering the gate structure are formed on the front side of the wafer. At least a polysilicon layer and a second insulating layer covering the polysilicon layer are formed on the back side of the wafer. Subsequently, at least a source/drain is formed in the front side of the wafer. Next, the second insulating layer is removed from the back side of the wafer. After removing the second insulating layer, the polysilicon layer is removed from the back side of the wafer.

According to another aspect of the present invention, a method for manufacturing a semiconductor substrate is provided. According to the method for manufacturing the semiconductor substrate, a wafer having a front side and a back side is provided. At least a gate structure and a source/drain formed at respectively two sides of the gate structure are formed on the front side of the wafer. At least a polysilicon layer and an insulating layer covering the polysilicon layer are formed on the back side of the wafer. Next, a salicide blocking (hereinafter abbreviated as SAB) layer is formed on the front side of the wafer and followed by forming salicide layers on the front side of the wafer. After forming the salicide layers, the SAB layer is removed from the front side of the wafer and the insulating layer is simultaneously removed from the back side of the wafer. Subsequently, the polysilicon layer is removed from the back side of the wafer.

According to the method for manufacturing the semiconductor substrate provided by the present invention, the polysilicon layer formed on the back side of the wafer is removed after forming the source/drain or after removing the SAB layer. Therefore, no polysilicon residues will be remained on the back side of the wafer and thus cleanliness of the semiconductor substrate is improved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a flow chart illustrating a method for manufacturing a semiconductor substrate provided by a first preferred embodiment of the present invention.

FIGS. 2-7 are schematic drawings illustrating the method for manufacturing the semiconductor substrate provided by the first preferred embodiment of the present invention.

FIG. 8 is a flow chart illustrating a method for manufacturing a semiconductor substrate provided by a second preferred embodiment of the present invention.

FIGS. 9-12 are schematic drawings illustrating the method for manufacturing the semiconductor substrate provided by the second preferred embodiment of the present invention.

### DETAILED DESCRIPTION

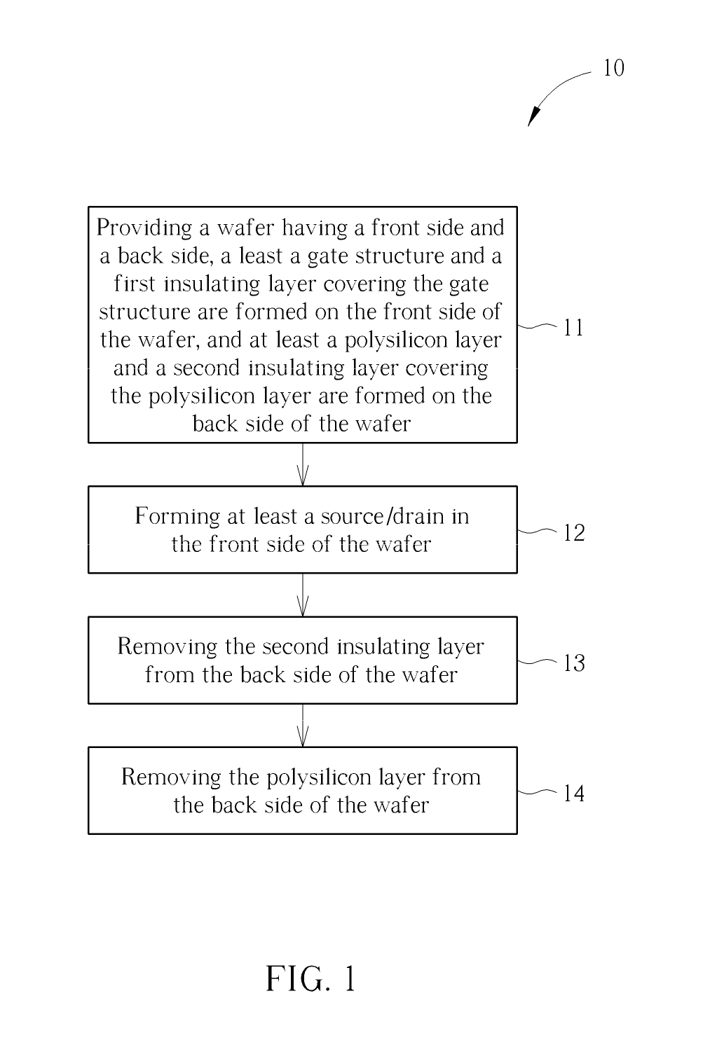

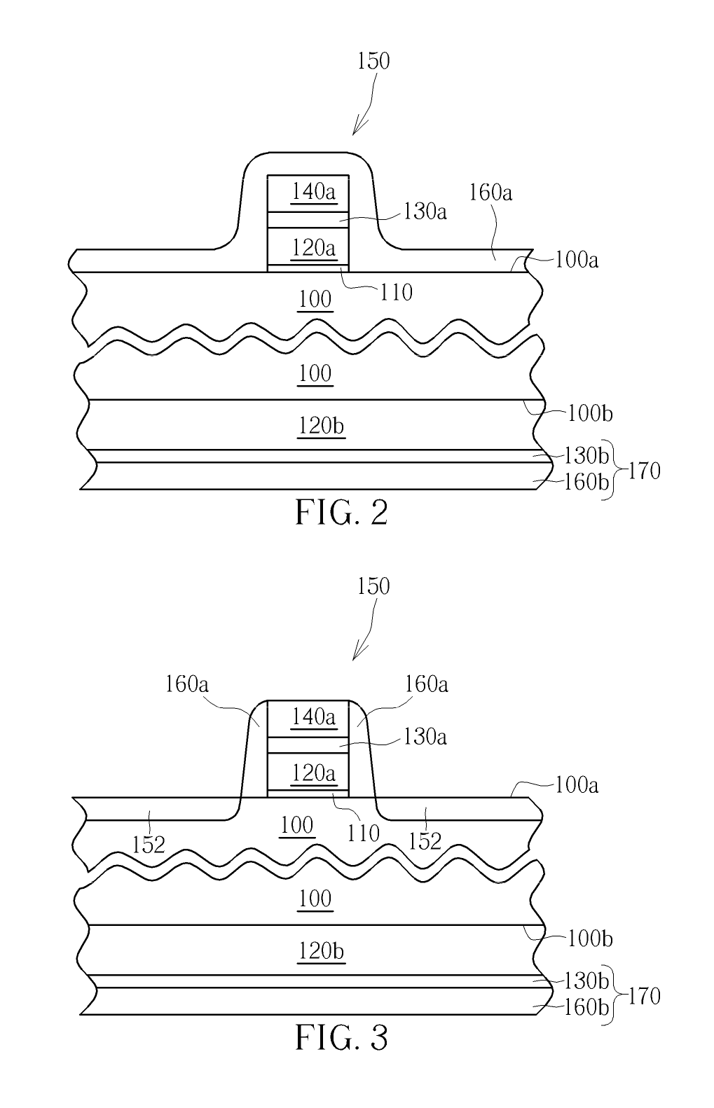

Please refer to FIGS. 1-7, wherein FIG. 1 is a flow chart illustrating a method for manufacturing a semiconductor substrate provided by a first preferred embodiment of the present invention and FIGS. 2-7 are schematic drawings illustrating the method for manufacturing the semiconductor substrate provided by the first preferred embodiment of the present invention.

As shown in FIG. 1, according to the provided method 10, a STEP 11 is performed:

STEP 11: providing a wafer having a front side and a back side, a least a gate structure and a first insulating layer covering the gate structure are formed on the front side of the wafer, and at least a polysilicon layer and a second insulating layer covering the polysilicon layer are formed on the back side of the wafer

Please refer to FIG. 2, simultaneously. According to the preferred embodiment, a wafer 100 is provided. As shown in FIG. 2, the wafer 100 includes a front side 100a and a back side 100b opposite to the front side 100a. It is well-known that the front side 100a of the wafer 100 accommodates devices for constructing integrated circuits, such as, for example but not limited to, flash memory cells in the preferred embodiment. Accordingly, a plurality of isolation structures (not shown) such as shallow trench isolations (STIs) are formed in the front side 100a of the wafer 100 for defining active regions and providing electrical isolation. An insulating layer 110a is formed on the front side 100a of the wafer 100, and followed by forming a polysilicon layer 120a on the insulating layer 110. It is noteworthy that, the polysilicon layer 120a is formed in a furnace, therefore a polysilicon layer 120b is concurrently formed on the back side of the wafer 100.

Thereafter, an insulating layer 130a, for example but not limited to an oxide-nitride-oxide (hereinafter abbreviated as ONO) layer, is formed on the polysilicon layer 120a and an insulating layer 130b made of the same material is concurrently formed on the polysilicon layer 120b. In other words, the insulating layer 130a is formed on the front side 100a of the wafer 100, and the insulating layer 130b is formed on the back side 100b of the wafer 100. After forming the insulating layers 130a/130b, another polysilicon layer 140a is formed on the front side 100a of the wafer 100. Next, the polysilicon layer 140a, the insulating layer 130a, the polysilicon layer 120a, and the insulating layer 110 on the front side 100a of the wafer 100 are patterned to form at least a gate structure 150. It is noteworthy that the gate structure 150 includes the insulating layer 110 serving as a tunneling dielectric layer, the polysilicon layer 120a serving as a floating gate, the insulating layer 130a serving as an interpoly dielectric layer, and the polysilicon layer 140a serving as a control gate. As shown in FIG. 2, the control gate 140a is formed on the floating gate 120a but electrically isolated from the floating gate 120a by the interpoly dielectric layer 130a.

Please refer to FIG. 2 again. Lightly doped drain (LDD) implantation can be performed to form LDDs if required. Next, a sidewall insulating layer 160a is formed on the front side 100a of the wafer 100. The sidewall insulating layer 160a preferably includes tetraethylorthosilicate (TEOS), but not limited to this. It is noteworthy that a sidewall insulating layer 160b made of the same material is concurrently formed on the back side 100b of the wafer 100. As shown in FIG. 2, the sidewalls insulating layer 160b is formed directly on and in contact with the insulating layer 130b on the back side 100b of the wafer 100. Therefore, a multi-layered insulating layer 170 including the insulating layer 130b and the sidewall insulating layer 160b is obtained on the back side 100b of the wafer 100.

Please refer to FIGS. 1 and 3. Then, STEP 12 is performed:

STEP 12: forming at least a source/drain in the front side of the wafer

Please refer to FIG. 3. After forming the sidewall insulating layer 160a/160b, an etching back process is performed to remove a portion of the sidewall insulating layer 160a from the front side 100a of the wafer 100. Consequently, the sidewall insulating layer 160a remained on the front side 100a of the wafer serves as spacers respectively on sidewalls of the gate structure 150 as shown in FIG. 3. Subsequently, a source/drain 152 is formed at respective two sides of the gate structure 150 in the front side 100a of the wafer 100. Typically, the source/drain 152 is formed by sequentially performing ion implantation and anneal process for driving-in. It should be noted that up till here, conventional processes may be used.

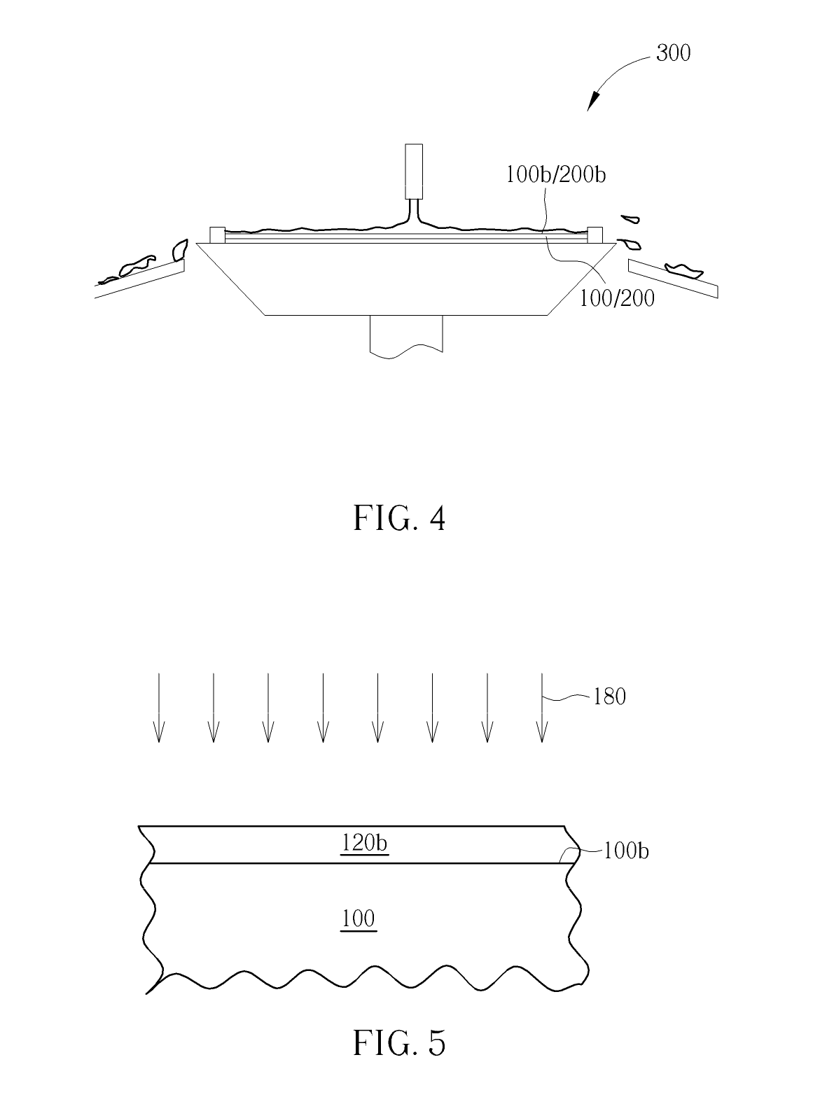

Please refer to FIG. 4. Next, the wafer 100 is flipped over to expose the back side 100b of the wafer 100 and mounted to a cleaning apparatus 300. That is, the wafer 100 is disposed on the cleaning apparatus 200 with the back side 100b upwardly placed. It should be understood that the cleaning apparatus 300 may be any such apparatus for single wafer cleaning known in the art.

Please refer to FIGS. 1 and 5. Then, STEP 13 is performed:

STEP 13: removing the second insulating layer from the back side of the wafer

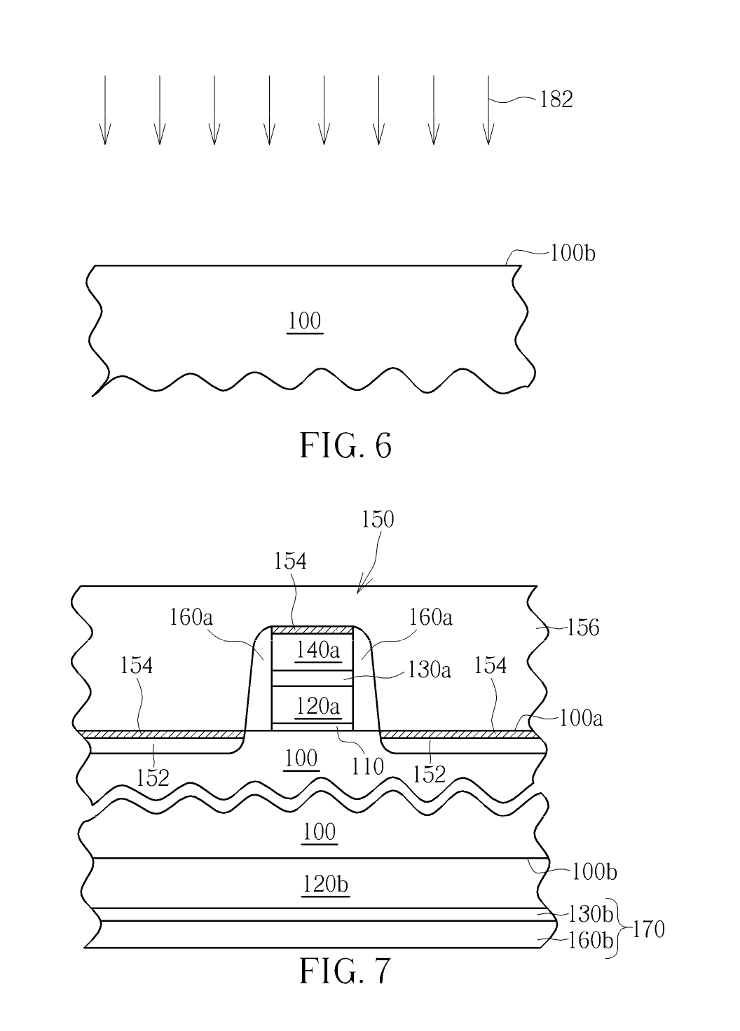

As shown in FIG. 5, the multi-layered insulating layer 170 is removed by diluted hydrofluoric acid (hereinafter abbreviated as DHF) 180. It should be noted that, only back side 100b of the wafer 100 is shown in FIGS. 5-6. Because the front side 100a of the wafer 100 is irrespective of and impervious to the removal of the multi-layered insulating layer 170, the front side 100a of the wafer 100 is omitted in the interest of brevity. In accordance with the preferred embodiment, a concentration of DHF 180 is about 49%, and a duration of removing the multi-layered insulating layer 170 is between 15 seconds (sec.) and 20 sec, but not limited to this.

Please refer to FIGS. 1 and 6. Then, STEP 14 is performed:

STEP 14: removing the polysilicon layer from the back side of the wafer

As shown in FIG. 6, the polysilicon layer 120b is removed by a DHF and nitric acid (hereinafter abbreviated as DHF HNO₃) mixture 182. In accordance with the preferred embodiment, a concentration of DHF is about 49% and a concentration of HNO₃ is about 70%. A ratio of DHF and HNO₃ is 1:120. And a duration of removing the polysilicon layer 120b is between 45 sec. and 60 sec.

Please refer to FIG. 7. After removing the polysilicon layer 120b from the back side 100b of the wafer 100, the wafer 100 is removed from the cleaning apparatus 200 and flipped back to expose the front side 100a of the wafer 100. It should be noted that no extra layer is remained on the back side 100b of the wafer 100 as shown in FIG. 7. Thereafter, salicide layers 154 are formed on the front side 100a of the wafer 100, particularly formed on surfaces of the gate structure 150 and the source/drain 152. After forming the salicide layer 154, an interlayer dielectric (hereinafter abbreviated as ILD) layer 156 is blanketly formed on the front side 100a of the wafer 100. Since processes for forming the salicide layers 154 and the ILD layer 156 are well-known to those skilled in the art, those details are omitted for simplicity.

According to the method for manufacturing the semiconductor substrate provided by the preferred embodiment, a two-stepped cleaning process is performed to sequentially remove the multi-layered insulating layer 170 and the polysilicon layer 120b. It is noteworthy that the removal of the multi-layered insulating layer 170 and the removal of the polysilicon layer 120b are all performed after forming the source/drain 152, particularly after the anneal process for driving-in. As mentioned above, the gate structure 150 and the source/drain 152 can be formed by any conventional process, therefore the method for manufacturing the semiconductor substrate provided by the preferred embodiment can be used in any semiconductor fabrication process in state-of-the-art. More important, since the polysilicon layer 120b is removed from the back side 100b of the wafer 100, no silicon residues/contamination is left on the back side 100b, and thus back side dirty issue is eliminated.

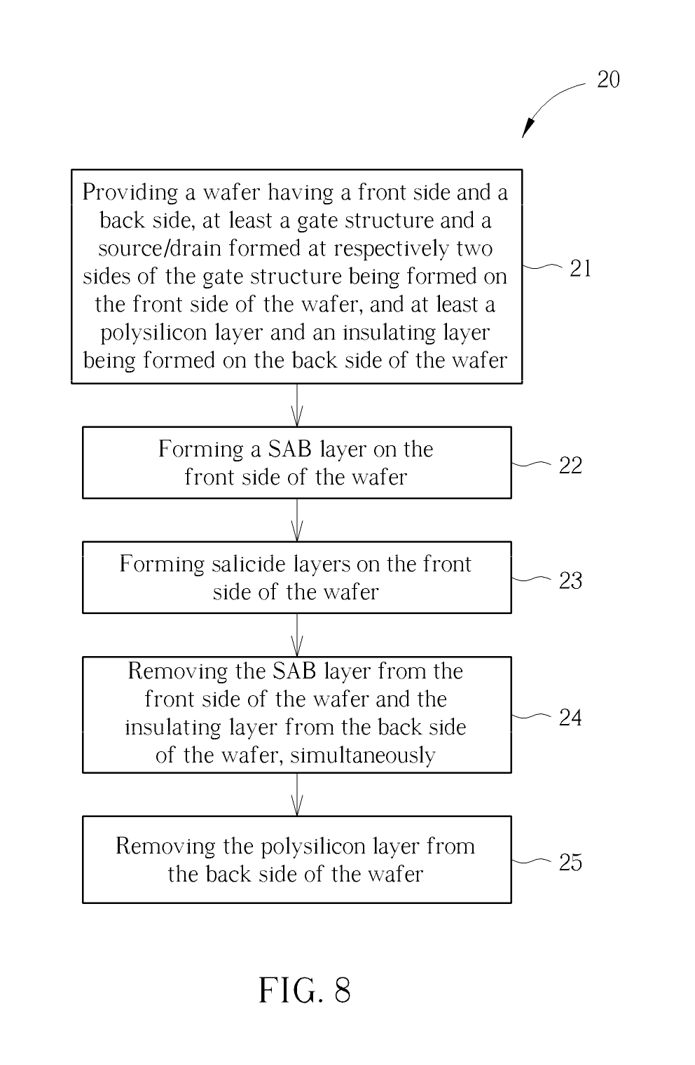

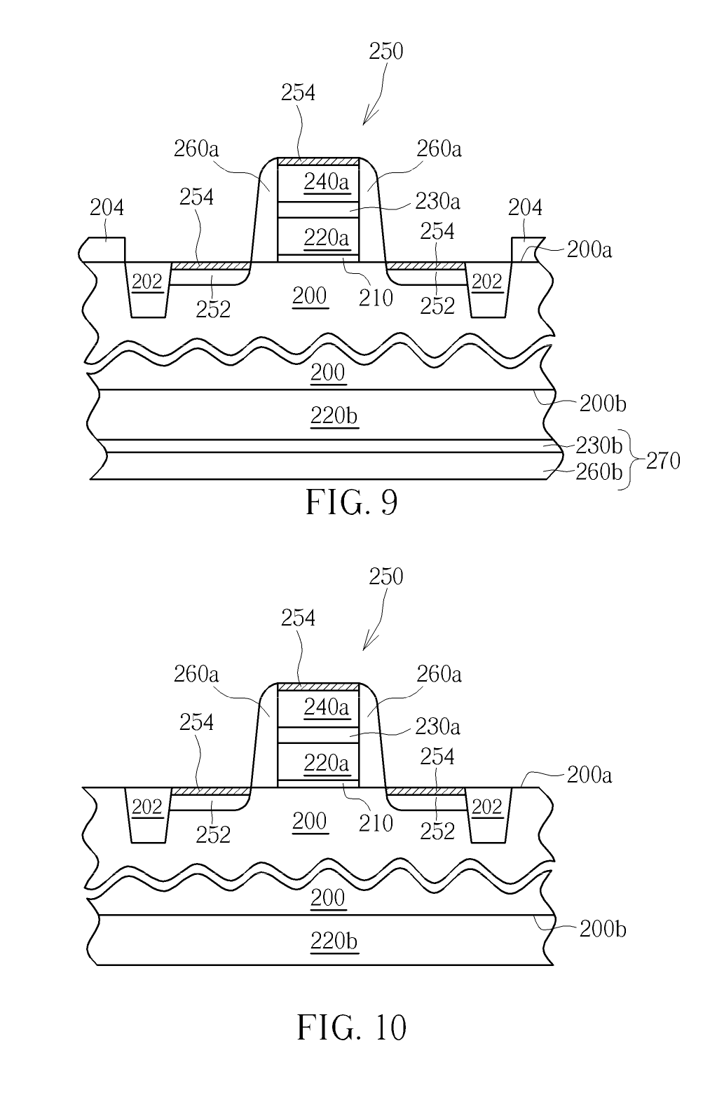

Please refer to FIGS. 8-12, wherein FIG. 8 is a flow chart illustrating a method for manufacturing a semiconductor substrate provided by a second preferred embodiment of the present invention and FIGS. 9-12 are schematic drawings illustrating the method for manufacturing the semiconductor substrate provided by the second preferred embodiment of the present invention. As shown in FIG. 8, according to the provided method 20, a STEP 21 is performed:

STEP 21: providing a wafer having a front side and a back side, at least a gate structure and a source/drain formed at respectively two sides of the gate structure being formed on the front side of the wafer, and at least a polysilicon layer and an insulating layer being formed on the back side of the wafer

Please refer to FIG. 9 simultaneously. According to the preferred embodiment, a wafer 200 is provided. As shown in FIG. 9, the wafer 200 includes a front side 200a and a back side 200b opposite to the front side 200a. It is well-known that the front side 200a of the wafer 200 accommodates devices for constructing integrated circuits, such as, for example but not limited to, flash memory cells in the preferred embodiment. Accordingly, a plurality of isolation structures 202 such as STIs are formed in the front side 200a of the wafer 200 for defining active regions and providing electrical isolation. An insulating layer 210 is formed on the front side 200a of the wafer 200, and followed by forming a polysilicon layer 220a on the insulating layer 210. It is noteworthy that, the polysilicon layer 220a is formed in a furnace, therefore a polysilicon layer 220b is concurrently formed on the back side 200b of the wafer 200.

Thereafter, another insulating layer 230a, for example but not limited to an ONO layer, is formed on the front side 200a of the wafer 200, and an insulating layer 230b made of the same material is concurrently formed on the back side 200b of the wafer 200. After forming the insulating layers 230a/230b, another polysilicon layer 240a is formed on the front side 200a of the wafer 200. Next, the polysilicon layer 240a, the insulating layer 230a, the polysilicon layer 220a, and the insulating layer 210 on the front side 200a of the wafer 200 are patterned to form at least a gate structure 250. It is noteworthy that the gate structure 250 includes the insulating layer 210 serving as a tunneling dielectric layer, the polysilicon layer 220a serving as a floating gate, the insulating layer 230a serving as an interpoly dielectric layer, and the polysilicon layer 240a serving as a control gate. As shown in FIG. 9, the control gate 240a is formed on the floating gate 220a but electrically isolated from the floating gate 220a by the insulating layer 230a.

Please refer to FIG. 9 again. Next, a sidewall insulating layer 260a is formed on the front side 100a of the wafer 100. The sidewall insulating layer 260a preferably includes TEOS, but not limited to this. It is noteworthy that a sidewall insulating layer 260b made of the same material is concurrently formed on the back side 200b of the wafer 200. As shown in FIG. 9, the sidewalls insulating layer 260b is formed directly on and in contact with the insulating layer 230b on the back side 100b of the wafer 200. Therefore, a multi-layered insulating layer 270 including the insulating layer 230b and the sidewall insulating layer 260b is obtained on the back side 200b of the wafer 200.

Please still refer to FIG. 9. After forming the sidewall insulating layer 260a/260b, an etching back process is performed to remove a portion of the sidewall insulating layer 260a from the front side 200a of the wafer 200. Consequently, the sidewall insulating layer 260a remained on the front side 200a of the wafer 200 serves as spacer as shown in FIG. 9. Subsequently, a source/drain 252 is formed at respective two sides of the gate structure 250 in the front side 200a of the wafer 200 as shown in FIG. 9.

Please refer to FIGS. 8. Then, STEP 22 and STEP 23 are sequentially performed:

STEP 22: forming a SAB layer on the front side of the wafer

STEP 23: forming salicide layers on the front side of the wafer

As shown in FIG. 9, a salicide blocking (SAB) layer 204 is formed on the front side 200a of the wafer 200. The SAB layer 204 includes dielectric material, typically silicon nitride, but not limited to this. It is desirable to exclude salicide from the some regions and therefore, the SAB layer 204 is formed and used to prevent salicide formation in these regions. Next, salicide layers 254 are formed on surfaces exposed by the SAB layer 204. As shown in FIG. 9, the salicide layers 254 are formed on the surfaces of the gate structure 250 and the source/drain 252.

Please refer to FIGS. 8 and 10. Then, STEP 24 is performed:

STEP 24: removing the SAB layer from the front side of the wafer and the insulating layer from the back side of the wafer, simultaneously

As shown in FIG. 10, removal of the SAB layer 204 is necessary in the semiconductor fabrication process, and any suitable etchant can be used in the removal. More important, the multi-layered insulating layer 270 is simultaneously removed from the back side 200b of the wafer 200 during removing the SAB layer 204, and thus the polysilicon layer 220b is exposed as shown in FIG. 10.

Please refer to FIG. 4. Next, the wafer 200 is flipped to expose the back side 200b of the wafer 200 and mounted to a cleaning apparatus 300. That is, wafer 200 is disposed on the cleaning apparatus 200 with the back side 200b upwardly placed. It should be understood that the cleaning apparatus 300 may be any such apparatus for single wafer cleaning known in the art.

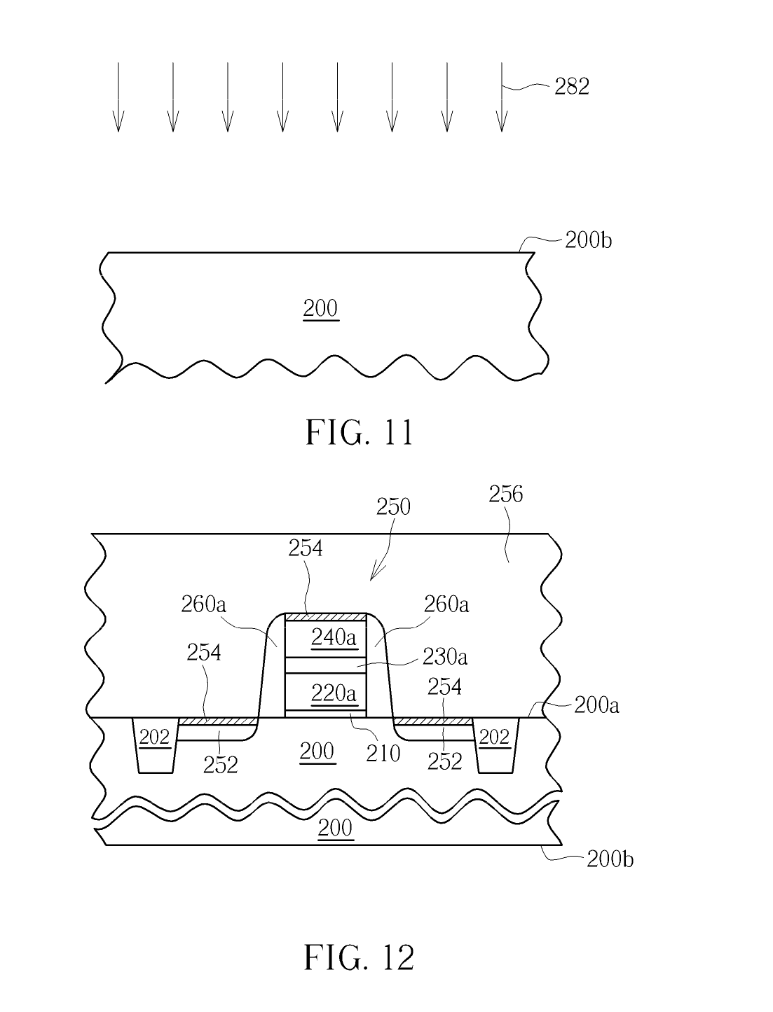

Please refer to FIGS. 8 and 11. Then, STEP 25 is performed:

STEP 25: removing the polysilicon layer from the back side of the wafer

It should be noted that, because the front side 200a of the wafer 200 is irrespective of and impervious to the ensuing steps, front side 200a of the wafer 200 is omitted in the interest of brevity. As shown in FIG. 11, the polysilicon layer 220b is removed by a DHF HNO₃ mixture 282. In accordance with the preferred embodiment, a concentration of DHF is about 49% and a concentration of HNO₃ is about 70%. A ratio of DHF and HNO₃ is 1:120. And a duration of removing the polysilicon layer 220b is between 45 sec. and 60 sec.

Please refer to FIG. 12. After removing the polysilicon layer 220b from the back side 200b of the wafer 200, the wafer 200 is removed from the cleaning apparatus 300 and flipped back to expose the front side 200a of the wafer 200. It should be noted that no extra layer is remained on the back side 200b of the wafer 200 as shown in FIG. 12. Thereafter, an ILD layer 256 is blanketly formed on the front side 200a of the wafer 200. Since process for forming the ILD layer 256 is well-known to those skilled in the art, those details are omitted for simplicity.

According to the method for manufacturing the semiconductor substrate provided by the preferred embodiment, a one-stepped cleaning process is performed to remove the polysilicon layer 220b. It is noteworthy since the removal of the SAB layer 204 is always performed in the semiconductor fabrication process and the removal of the SAB layer 204 simultaneously removes the multi-layered insulating layer 270 from the back side 200b of the wafer 200, one step of cleaning is economized, and thus only the removal of the polysilicon layer 220b is required. Additionally, the multi-layered insulating layer 270 also can be simultaneously removed during removing the disposal spacer in the selective strain scheme (SSS).

Furthermore, since the removal of the polysilicon layer 220b is performed after removing the SAB layer 204, the method for manufacturing the semiconductor substrate provided by the preferred embodiment can be used in any semiconductor fabrication process in state-of-the-art. More important, since the polysilicon layer 220b is removed from the back side 200b of the wafer 200, no silicon residues/contamination is left on the back side 200b, and thus back side dirty issue is eliminated.

According to the method for manufacturing the semiconductor substrate provided by the present invention, the polysilicon layer formed on the back side of the wafer is removed after forming the source/drain or after removing the SAB layer. Therefore, no polysilicon residues will be remained on the back side of the wafer and thus cleanliness of the semiconductor substrate is improved. Additionally, the method for manufacturing the semiconductor substrate provided by the present invention can be used in not only the flash memory approach, but also the conventional metal-oxide-semiconductor (MOS) transistor device and the replacement metal gate approach, as long as the polysilicon gate is required.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for manufacturing a semiconductor substrate, comprising:
providing a wafer having a front side and a back side, at least a gate structure and a first insulating layer covering the gate structure being formed on the front side of the wafer, and at least a polysilicon layer and a second insulating layer covering the polysilicon layer being formed on the back side of the wafer;
forming at least a source/drain in the front side of the wafer;
removing the second insulating layer from the back side of the wafer; and
removing the polysilicon layer from the back side of the wafer.

2. The method for manufacturing the semiconductor substrate according to claim 1, further comprising removing a portion of the first insulating layer to form spacers respectively on sidewalls of the gate structure.

3. The method for manufacturing the semiconductor substrate according to claim 1, wherein the second insulating layer comprises a multi-layered insulating layer.

4. The method for manufacturing the semiconductor substrate according to claim 1, further comprising flipping the wafer to expose the back side of the wafer and mounting the wafer to a cleaning apparatus.

5. The method for manufacturing the semiconductor substrate according to claim 1, wherein the second insulating layer is removed by diluted hydrofluoric acid (DHF).

6. The method for manufacturing the semiconductor substrate according to claim 5, wherein a concentration of DHF is about 49%.

7. The method for manufacturing the semiconductor substrate according to claim 1, wherein a duration of removing the second insulating layer is between 15 seconds (sec.) and 20 sec.

8. The method for manufacturing the semiconductor substrate according to claim 1, wherein the polysilicon layer is removed by a DHF and nitric acid (HNO₃) mixture.

9. The method for manufacturing the semiconductor substrate according to claim 8, wherein a concentration of DHF is about 49% and a concentration of HNO₃ is about 70%.

10. The method for manufacturing the semiconductor substrate according to claim 9, wherein a ratio of DHF and HNO₃ is 1:120.

11. The method for manufacturing the semiconductor substrate according to claim 1, wherein a duration of removing the polysilicon layer is between 45 sec. and 60 sec.

12. The method for manufacturing the semiconductor substrate according to claim 1, further comprising forming salicide layers on the front side of the wafer and forming an interlayer dielectric (ILD) layer on the front side of the wafer after removing the polysilicon layer from the back side of the wafer.

13. A method for manufacturing a semiconductor substrate, comprising:
providing a wafer having a front side and a back side, at least a gate structure and a source/drain formed at respective two sides of the gate structure being formed on the front side of the wafer, and at least a polysilicon layer and an insulating layer being formed on the back side of the wafer;
forming a salicide blocking (SAB) layer on the front side of the wafer;
forming salicide layers on the front side of the wafer;
removing the SAB layer from the front side of the wafer and the insulating layer from the back side of the wafer, simultaneously; and
removing the polysilicon layer from the back side of the wafer.

14. The method for manufacturing a semiconductor substrate according to claim 13, wherein the insulating layer comprises a multi-layered insulating layer.

15. The method for manufacturing a semiconductor substrate according to claim 13, further comprising flipping the wafer to expose the back side of the wafer and mounting the wafer to a cleaning apparatus.

16. The method for manufacturing the semiconductor substrate according to claim 13, wherein the polysilicon layer is removed by a DHF and HNO₃ mixture.

17. The method for manufacturing the semiconductor substrate according to claim 16, wherein a concentration of DHF is about 49% and a concentration of HNO₃ is about 70%.

18. The method for manufacturing the semiconductor substrate according to claim 17, wherein a ratio of DHF and HNO₃ is 1:120.

19. The method for manufacturing the semiconductor substrate according to claim 12, wherein a duration of removing the polysilicon layer is between 45 sec. and 60 sec.

20. The method for manufacturing the semiconductor substrate according to claim 13, further comprising forming an ILD layer on the front side of the wafer after removing the polysilicon layer from the back side of the wafer.
